(19) United States
(12) Patent Application Publication
(10) Pub. No.: US 2025/0194395 A1
(43) Pub. Date: Jun. 12, 2025

(54) STRETCHABLE DEVICE

(71) Applicant: Japan Display Inc., Tokyo (JP)

(72) Inventors: Yosuke HYODO, Tokyo (JP); Takumi SANO, Tokyo (JP)

(73) Assignee: Japan Display Inc., Tokyo (JP)

(21) Appl. No.: 18/963,842

(22) Filed: Nov. 29, 2024

(30) Foreign Application Priority Data
Dec. 6, 2023 (JP) 2023-206346

(51) Int. Cl. H10K 77/10

(52) U.S. Cl. CPC H10K 77/111

(57) ABSTRACT

According to an aspect, a stretchable device includes a stretchable substrate including a resin base member and an array layer stacked in sequence. The resin base member includes: bodies spaced apart from each other in a planar direction; and hinges that meander and extend in the planar direction and couple the bodies. Each hinge has an arc having an arc shape. Part of the array layer stacked on the hinge is a hinge array layer. Part of the hinge array layer stacked on the arc is an arc array layer having an arc shape. The width of the arc array layer from an inner periphery to an outer periphery is smaller than the width of the arc from an inner periphery to an outer periphery. The inner periphery of the arc array layer is disposed away from the inner periphery of the arc toward the outer periphery of the arc.

### CROSS-REFERENCE TO RELATED APPLICATION

This application claims the benefit of priority from Japanese Patent Application No. 2023-206346 filed on Dec. 6, 2023, the entire contents of which are incorporated herein by reference.

### BACKGROUND

### 1. Technical Field

What is disclosed herein relates to a stretchable device.

### 2. Description of the Related Art

Stretchable devices include a stretchable substrate with excellent elasticity and flexibility. As described in Japanese Patent Application Laid-open Publication No. 2022-158622 and Japanese Patent Application Laid-open Publication No. 2022-049511, a stretchable substrate includes an array layer including electrical circuits and a resin base member serving as the base member for the array layer. The resin base member includes bodies arrayed in a matrix (row-column configuration) and hinges that couple the bodies to each other. Each hinge includes a plurality of arcs and has a meandering shape. When a tensile load acts on the stretchable device, the arcs of the hinge expand. As a result, the bodies are separated from each other, and the stretchable device stretches. When the arc deforms, a tensile strain is generated in the inner peripheral portion of the arc, and a compressive strain is generated in the outer peripheral portion of the arc.

The array layer includes a plurality of insulating layers. The insulating layers are also stacked on the arcs of the hinges. In the following description, the part of the array layer (insulating layers) stacked on the arc is referred to as an arc array layer. The insulating layer has smaller elongation than the resin base member. When a large tensile load acts on the array layer, cracks are likely to be generated in the inner peripheral portion of the arc array layer.

For the foregoing reasons, there is a need for a stretchable device that makes the inner peripheral portion of an arc array layer less susceptible to cracks.

### SUMMARY

According to an aspect, a stretchable device includes a stretchable substrate including a resin base member and an array layer stacked in sequence. The resin base member includes: a plurality of bodies spaced apart from each other in a planar direction intersecting a stacking direction in which the resin base member and the array layer are stacked; and a plurality of hinges that meander and extend in the planar direction and couple the bodies. Each of the hinges has an arc having an arc shape when viewed in the stacking direction. A part of the array layer stacked on the hinge is a hinge array layer. A part of the hinge array layer stacked on the arc is an arc array layer having an arc shape. The width of the arc array layer from an inner periphery to an outer periphery is smaller than the width of the arc from an inner periphery to an outer periphery. The inner periphery of the arc array layer is disposed away from the inner periphery of the arc toward the outer periphery of the arc.

### BRIEF DESCRIPTION OF THE DRAWINGS

FIG. 1 is a schematic of a stretchable device according to a first embodiment;

FIG. 2 is a schematic of a section of the stretchable device according to the first embodiment, and more specifically a sectional view along line II-II of FIG. 3;

FIG. 3 is an enlarged view of part of a resin base member according to the first embodiment when viewed from a first stacking direction;

FIG. 4 is an enlarged view of a longitudinal hinge according to the first embodiment;

FIG. 5 is an enlarged view of the longitudinal hinge according to the first embodiment when a tensile load in a first direction is applied thereto;

FIG. 6 is a schematic of the components of a load detection circuit disposed on a body according to the first embodiment;

FIG. 7 is a diagram schematically illustrating a Wheatstone bridge circuit according to the first embodiment;

FIG. 8 is an enlarged view of an array layer according to the first embodiment when viewed from the first stacking direction;

FIG. 9 is a sectional view seen in the direction of arrow along line IX-IX of FIG. 8;

FIG. 10 is a sectional view for explaining a first step of a bending test;

FIG. 11 is a sectional view for explaining a second step of the bending test;

FIG. 12 is a sectional view for explaining a third step of the bending test;

FIG. 13 is an enlarged view of the array layer according to a first modification when viewed from the first stacking direction; and

FIG. 14 is an enlarged view of the array layer according to a second modification when viewed from the first stacking direction.

### DETAILED DESCRIPTION

Exemplary embodiments to embody the present disclosure are described below in greater detail with reference to the accompanying drawings. The contents described in the embodiments below are not intended to limit the invention according to the present disclosure. Components described below include components easily conceivable by those skilled in the art and components substantially identical therewith. Furthermore, the components described below may be appropriately combined. What is disclosed herein is given by way of example only, and appropriate modifications made without departing from the spirit of the present invention and easily conceivable by those skilled in the art naturally fall within the scope of the present invention. To simplify the explanation, the drawings may possibly illustrate the width, the thickness, the shape, and other elements of each unit more schematically than the actual aspect. These elements, however, are given by way of example only and are not intended to limit interpretation of the present invention. In the present specification and the drawings, components similar to those previously described with reference to previous drawings are denoted by the same reference numerals, and detailed explanation thereof may be appropriately omitted.

When the term “on” is used to describe an aspect where a first structure is disposed on or above a second structure in the present specification and the claims, it includes both of the following cases unless otherwise noted: a case where the first structure is disposed on and in contact with the second structure, and a case where the first structure is disposed above the second structure with still another structure interposed therebetween.

### First Embodiment

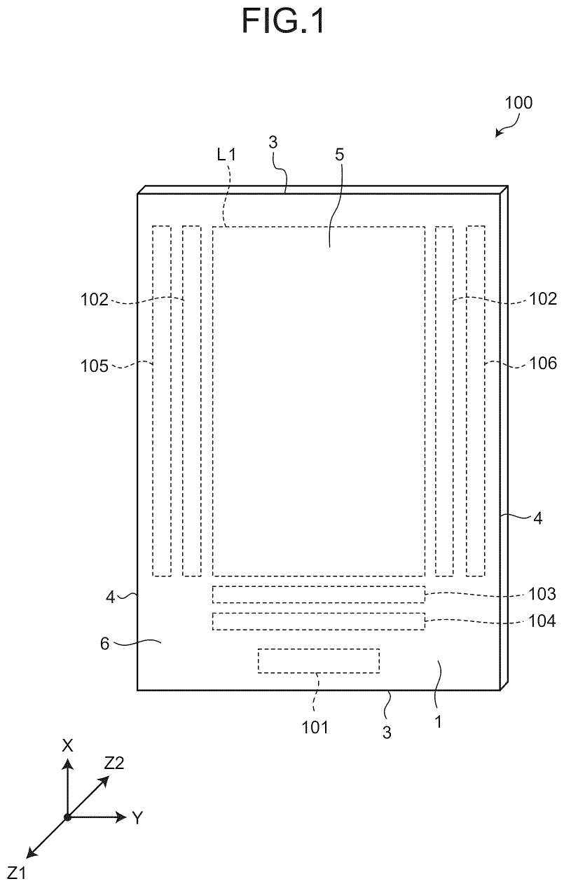

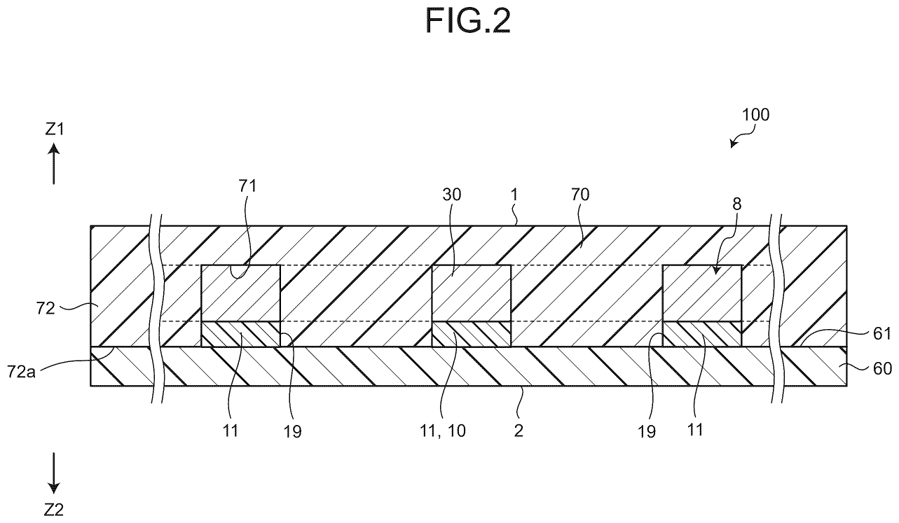

FIG. 1 is a schematic of a stretchable device according to a first embodiment. As illustrated in FIG. 1, this stretchable device 100 has a flat plate shape. The stretchable device 100 has a surface 1 and a back surface 2 (the back surface 2 is not illustrated in FIG. 1, and refer to FIG. 2) facing opposite to each other.

In the following description, the direction parallel to the surface 1 and the back surface 2 is referred to as a planar direction. A direction parallel to the planar direction is referred to as a first direction X. A direction parallel to the planar direction and intersecting the first direction X is referred to as a second direction Y.

The stretchable device 100 has a rectangular (quadrilateral) shape in plan view. The surface 1 has a pair of short sides 3 and a pair of long sides 4. The long side 4 is parallel to the first direction X. The short side 3 is parallel to the second direction Y. Thus, the first direction X and the second direction Y according to the present embodiment are orthogonal to each other.

The stretchable device 100 is, in plan view, divided into a detection region 5 and a peripheral region 6. The detection region 5 is a region in which a load applied to the stretchable device 100 can be detected. The peripheral region 6 is a frame-shaped region surrounding the outer periphery of the detection region 5. In FIG. 1, a boundary line L1 is illustrated to make the boundary between the detection region 5 and the peripheral region 6 easy to understand.

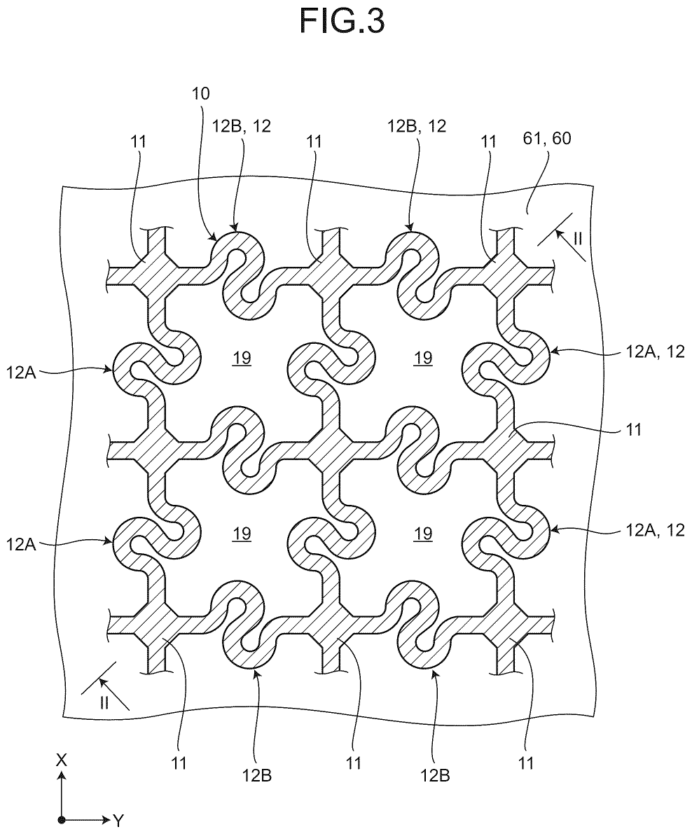

FIG. 2 is a schematic of a section of the stretchable device according to the first embodiment, and more specifically a sectional view along line II-II of FIG. 3. As illustrated in FIG. 2, the stretchable device 100 includes a first stretchable resin 60, a resin base member 10, an array layer 30, and a second stretchable resin 70 stacked in order in a first stacking direction Z1. The resin base member 10 and the array layer 30 constitute a stretchable substrate 8.

The direction in which the first stretchable resin 60, the resin base member 10, the array layer 30, and the second stretchable resin 70 are stacked is hereinafter referred to as a stacking direction. In the stacking direction, the direction in which the second stretchable resin 70 is disposed when viewed from the first stretchable resin 60 is referred to as a first stacking direction Z1, and the direction opposite to the first stacking direction Z1 is referred to as a second stacking direction Z2. The view of the stretchable device 100 as viewed from a point positioned in the first stacking direction Z1 is referred to as plan view.

The first stretchable resin 60 and the second stretchable resin 70 have insulating, elastic, and flexible properties. The resin used as the first stretchable resin 60 and the second stretchable resin 70 is acrylic elastomer, for example. The first stretchable resin 60 and the second stretchable resin 70 according to the present disclosure are not limited to acrylic elastomer. They may be acrylic resin, epoxy resin, urethane resin, or the like and are not particularly limited.

The first stretchable resin 60 and the second stretchable resin 70 are formed in a plate shape and extend in the planar direction. The surface of the first stretchable resin 60 in the second stacking direction Z2 serves as the back surface 2 of the stretchable device 100. The first stretchable resin 60 has a first surface 61 facing the first stacking direction Z1. The resin base member 10 is stacked on the first surface 61.

The surface of the second stretchable resin 70 in the first stacking direction Z1 serves as the surface 1 of the stretchable device 100. A surface 71 of the second stretchable resin 70 in the second stacking direction Z2 adheres to the array layer 30. The ends of the second stretchable resin 70 in the first direction X and in the second direction Y are provided with a frame part 72 that protrudes in the second stacking direction Z2 from the surface 71.

The frame part 72 is formed in an annular shape in plan view and surrounds the outer periphery of the resin base member 10 and the array layer 30. A surface 72a of the frame part 72 in the second stacking direction Z2 adheres to the first surface 61 of the first stretchable resin 60. Thus, the first stretchable resin 60 and the second stretchable resin 70 cooperate to serve as a housing that accommodates the resin base member 10 and the array layer 30.

The resin base member 10 adheres to the first surface 61 of the first stretchable resin 60. The resin base member 10 has elastic, flexible, and insulating properties. The resin base member 10 is made of resin member, such as non-photosensitive polyimide. Therefore, the elongation of the resin base member 10 according to the embodiment is 30%.

FIG. 3 is an enlarged view of part of the resin base member according to the first embodiment when viewed from a point positioned in the first stacking direction Z1. As illustrated in FIG. 3, the resin base member 10 includes a plurality of bodies 11 and a plurality of hinges 12 meandering and extending in the planar direction. The resin base member 10 is disposed in the detection region 5 and the peripheral region 6, which is not specifically illustrated.

The body 11 has an octagonal shape in plan view. The bodies 11 are arrayed in the first direction X and the second direction Y and are separated from one another. The shape of the body 11 according to the present disclosure in plan view is not limited to an octagonal shape and may be circular or other polygonal shapes.

The hinge 12 couples the bodies 11 adjacent to each other. The hinges 12 include two kinds of hinges: a longitudinal hinge 12A extending in the first direction X, and a lateral hinge 12B extending in the second direction Y. The part not provided with the bodies 11 or the hinges 12 in the resin base member 10 serves as a through hole 19 passing through the resin base member 10 in the stacking direction. In other words, the resin base member 10 has a plurality of through holes 19.

As illustrated in FIG. 2, the array layer 30 is not stacked in the regions overlapping the through holes 19. The through holes 19 are filled with the second stretchable resin 70. With this configuration, the stretchable device 100 has low rigidity in the parts adjacent to the through holes 19 in the first direction X or the second direction Y and has elasticity and bendability (stretchability). In other words, when a load acts on the stretchable device 100, the hinges 12 deform. By contrast, the bodies 11 hardly deform, thereby reducing damage to functional elements (thin-film transistors 40) stacked on the bodies 11.

While the through hole 19 according to the present embodiment is filled with the second stretchable resin 70, the through hole 19 according to the present disclosure may be filled with the first stretchable resin 60. Alternatively, the through hole 19 may be filled with both the first stretchable resin 60 and the second stretchable resin 70. Still alternatively, the through hole 19 may be filled with resin material other than the first stretchable resin 60 or the second stretchable resin 70. Still alternatively, the through hole 19 may be a space provided with nothing.

Next, the hinge 12 is described in greater detail. When the longitudinal hinge 12A is rotated by 90 degrees, it has the same shape as that of the lateral hinge 12B. Therefore, the following describes the longitudinal hinge 12A as a representative example.

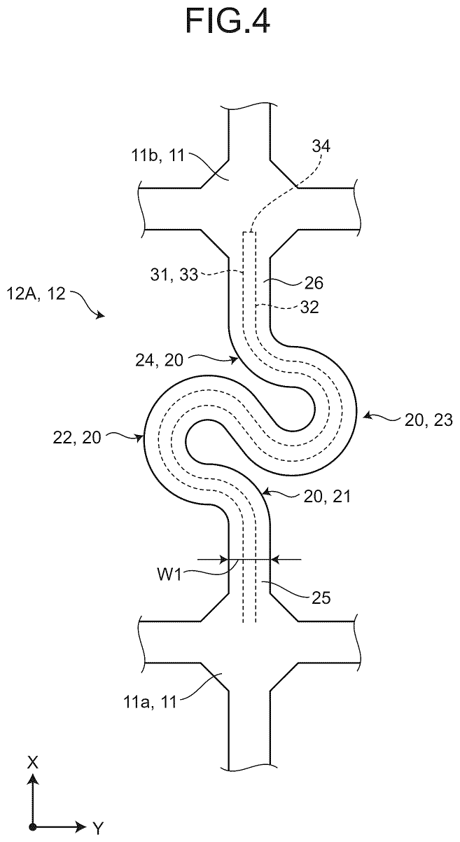

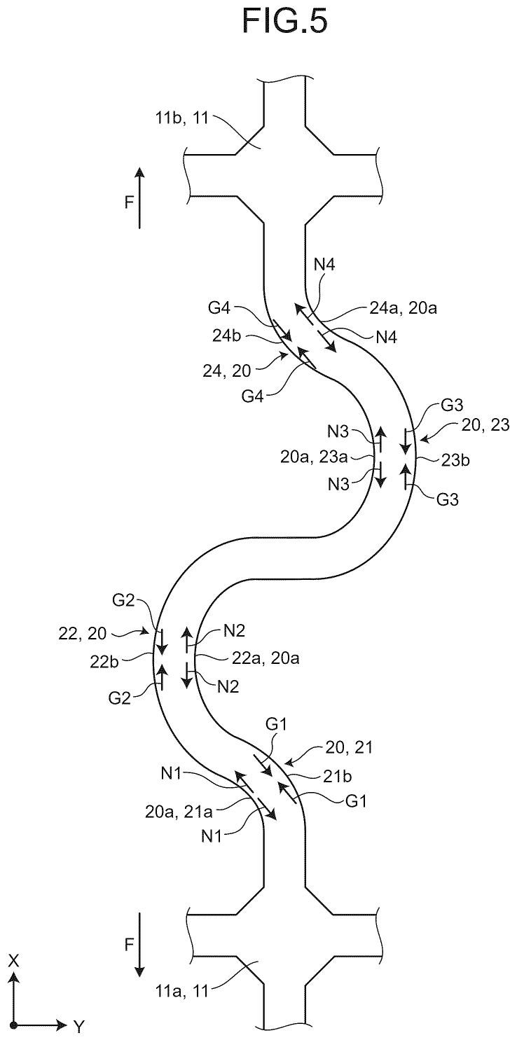

FIG. 4 is an enlarged view of the longitudinal hinge according to the first embodiment. FIG. 5 is an enlarged view of the longitudinal hinge according to the first embodiment when a tensile load in the first direction is applied thereto. For the convenience of explanation, one of the two bodies 11 that sandwich the longitudinal hinge 12A is referred to as a first body 11a, and the other is referred to as a second body 11b.

As illustrated in FIG. 4, the longitudinal hinge 12A has four arcs 20 formed in an arc shape in plan view. Therefore, the longitudinal hinge 12A extends in the first direction X while meandering in the second direction Y. The number of arcs 20 according to the present disclosure is not limited to four.

The four arcs 20 are a first arc 21, a second arc 22, a third arc 23, and a fourth arc 24 arranged in the order as listed, from the first body 11a to the second body 11b. The first arc 21 and the fourth arc 24 are each formed in a quadrant shape. The second arc 22 and the third arc 23 are each formed in a substantially semicircular arc shape.

The longitudinal hinge 12A has a linear first base 25 that couples the first body 11a and the first arc 21 and a linear second base 26 that couples the fourth arc 24 and the second body 11b.

The width W1 of the longitudinal hinge 12A is constant from one end of the longitudinal hinge 12A to the other. In other words, the width of each arc 20 is also W1.

As illustrated in FIG. 5, when a tensile load in the first direction X (refer to arrow F in FIG. 5) acts on the stretchable device 100, the radii of curvature of the first arc 21, the second arc 22, the third arc 23, and the fourth arc 24 increase. As a result, the distance from one end of the longitudinal hinge 12A to the other increases, and the bodies 11 move away from each other.

When the radius of curvature of each arc 20 increases, a tensile load (refer to arrows N1 to N4 in FIG. 5) acts on the inner peripheral portion of the arc 20. By contrast, a compressive load (refer to arrows G1 to G4 in FIG. 5) acts on the outer peripheral portion of the arc 20. In other words, in the first arc 21, a larger tensile strain is generated as closer to an inner periphery 21a. A larger compressive strain is generated as closer to an outer periphery 21b. Similarly, in the second arc 22, a larger tensile strain is generated as closer to an inner periphery 22a, and a larger compressive strain is generated as closer to an outer periphery 22b. In the third arc 23, a larger tensile strain is generated as closer to an inner periphery 23a, and a larger compressive strain is generated as closer to an outer periphery 23b. In the fourth arc 24, a larger tensile strain is generated as closer to an inner periphery 24a, and a larger compressive strain is generated as closer to an outer periphery 24b.

Next, the array layer 30 is described. The array layer 30 includes a plurality of insulating layers (not illustrated) stacked in the stacking direction and a load detection circuit buried in the insulating layers and insulated from the outside. The following describes the load detection circuit and the insulating layers in this order.

The load detection circuit provided to the array layer 30 is a circuit that detects a load in the planar direction applied to the stretchable device 100. An electrical circuit provided to the array layer 30 according to the present disclosure may be a circuit that detects force applied to the surface 1, for example, and is not particularly limited.

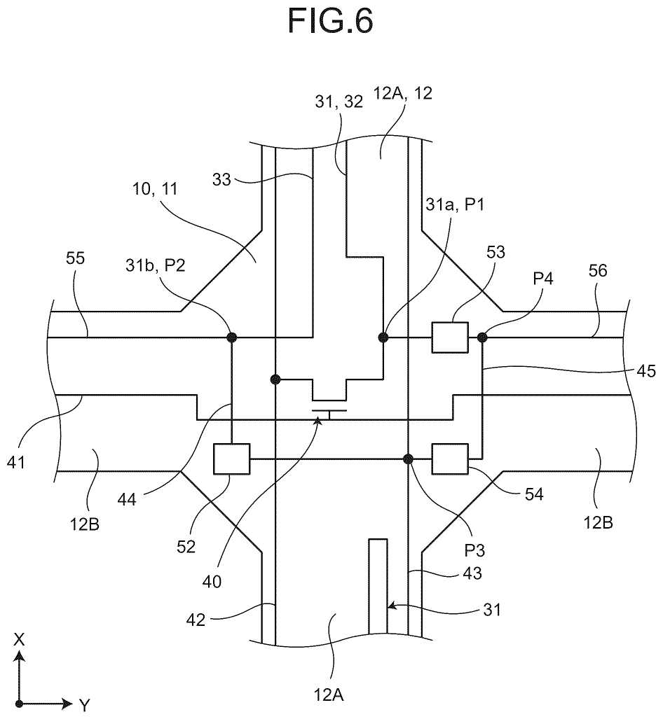

FIG. 6 is a schematic of the components of the load detection circuit disposed on the body according to the first embodiment. As illustrated in FIG. 6, the load detection circuit includes a strain gauge 31 (refer to FIG. 4), a thin-film transistor 40, a gate line 41, a first signal line 42, a second signal line 43, a first wiring line 44, a second wiring line 45, a second resistor 52, a third resistor 53, a fourth resistor 54, a first potential detection line 55, and a second potential detection line 56.

The strain gauge 31 is a detection element that stretches corresponding to the strain generated in the hinge 12 and increases or decreases the resistance. As illustrated in FIG. 4, the strain gauge 31 is provided only to each longitudinal hinge 12A. While the strain gauge 31 according to the present embodiment is provided only to the longitudinal hinge 12A, the strain gauge 31 according to the present disclosure may be provided only to the lateral hinge 12B or to both the longitudinal hinge 12A and the lateral hinge 12B.

The strain gauge 31 includes a first strain gauge 32, a second strain gauge 33, and a folded part 34. The first strain gauge 32 and the second strain gauge 33 extend along the longitudinal hinge 12A and are disposed parallel to each other. The folded part 34 is disposed on the second body 11b and couples the ends of the first strain gauge 32 and the second strain gauge 33.

The strain gauge 31 extends from the first body 11a to the second body 11b, folds back from the second body 11b, and returns to the first body 11a. In other words, the strain gauge 31 according to the present embodiment includes two strain gauges (the first strain gauge 32 and the second strain gauge 33). Therefore, the strain gauge 31 can detect a larger amount of strain and has higher detection sensitivity than in a case where it is composed of one strain gauge. The strain gauge according to the present disclosure may be composed of one strain gauge.

As illustrated in FIG. 6, one end of the first strain gauge 32 (start end 31a of the strain gauge 31) is disposed on the first body 11a. One end of the second strain gauge 33 (terminal end 31b of the strain gauge 31) is disposed on the first body 11a.

As illustrated in FIG. 6, the bodies 11 are each provided with one thin-film transistor 40. The source electrode (not illustrated) of the thin-film transistor 40 is coupled to the start end 31a of the strain gauge 31. The coupling point between the thin-film transistor 40 and the start end 31a of the strain gauge 31 is hereinafter referred to as a first coupling point P1.

The gate line 41 is disposed over a plurality of lateral hinges 12B and a plurality of bodies 11 and extends in the second direction Y. The gate line 41 is coupled to the gate electrode (not illustrated) of the thin-film transistor 40. A plurality of thin-film transistors 40 arrayed in the second direction Y are coupled to one gate line 41.

The first signal line 42 is disposed over a plurality of longitudinal hinges 12A and a plurality of bodies 11 and extends in the first direction X. Similarly, the second signal line 43 is disposed over a plurality of longitudinal hinges 12A and a plurality of bodies 11 and extends in the first direction.

The first signal line 42 is coupled to the drain electrode (not illustrated) of the thin-film transistor 40 in each body 11. Therefore, a plurality of thin-film transistors arrayed in the first direction X are coupled to one first signal line 42.

The first wiring line 44 is disposed on the body 11. One end of the first wiring line 44 is coupled to the terminal end 31b of the strain gauge 31. The coupling point between the first wiring line 44 and the terminal end 31b of the strain gauge 31 is hereinafter referred to as a first intermediate point P2. The other end of the first wiring line 44 is coupled to the second signal line 43. The coupling point between the first wiring line 44 and the second signal line 43 is hereinafter referred to as a second coupling point P3. A plurality of thin-film transistors 40 arrayed in the first direction X share one second signal line 43. The second resistor 52 is provided on the first wiring line 44.

The second wiring line 45 is disposed on the body 11. The second wiring line 45 couples the first coupling point P1 and the second coupling point P3. Therefore, the second wiring line 45 is a circuit parallel to the circuit composed of the strain gauge 31 and the first wiring line 44 with the start end 31a of the strain gauge 31 as a branch point. The third resistor 53 and the fourth resistor 54 are disposed on the second wiring line 45. A point positioned between the third resistor 53 and the fourth resistor 54 on the second wiring line 45 is hereinafter referred to as a second intermediate point P4.

The first potential detection line 55 is a wiring line extending from the first intermediate point P2 to detect the potential of the terminal end 31b of the strain gauge 31. The second potential detection line 56 is an electric wiring line extending from the second intermediate point P4 of the second wiring line 45 to detect the potential of the second intermediate point P4 of the second wiring line 45. The first potential detection line 55 is disposed over a plurality of lateral hinges 12B and a plurality of bodies 11 and extends on one side in the second direction Y. The second potential detection line 56 is disposed over a plurality of lateral hinges 12B and a plurality of bodies 11 and extends on the other side in the second direction Y.

As described above, the circuit including the strain gauge 31 according to the present embodiment serves as a Wheatstone bridge circuit. The following describes the Wheatstone bridge circuit according to the present embodiment in detail.

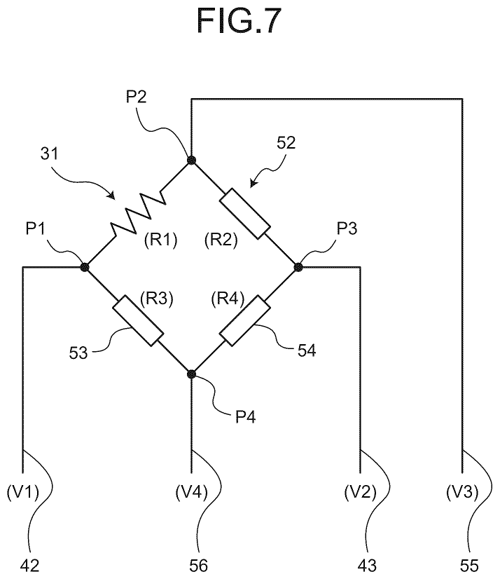

FIG. 7 is a diagram schematically illustrating the Wheatstone bridge circuit according to the first embodiment. A second resistance R2 of the second resistor 52, a third resistance R3 of the third resistor 53, and a fourth resistance R4 of the fourth resistor 54 are equal to a first resistance R1 of the strain gauge 31 when the hinge 12 is not deformed (R1=R2=R3=R4). The second resistor 52, the third resistor 53, and the fourth resistor 54 are provided to the body 11. Therefore, the amount of change in their resistances is zero when the hinge 12 is deformed.

As illustrated in FIG. 7, to detect the amount of strain by the strain gauge 31, the first signal line 42 is supplied with a detection signal having a predetermined first potential V1. The second signal line 43 is supplied with a second potential V2 lower than the first potential V1 (V2>V1). The second potential V2 according to the present embodiment is 0 V. Therefore, when the thin-film transistor 40 is ON, the potential of the first coupling point P1 (start end 31a of the strain gauge 31) becomes the first potential V1.

When the hinge 12 is not deformed, the first resistance R1 of the strain gauge 31 does not change. Thus, the first resistance R1 of the strain gauge 31, the second resistance R2 of the second resistor 52, the third resistance R3 of the third resistor 53, and the fourth resistance R4 of the fourth resistor 54 are equal to one another. Therefore, a potential V3 of the first intermediate point P2 read by the first potential detection line 55 is equal to a potential V4 of the second intermediate point P4 read by the second potential detection line 56.

By contrast, when the hinge 12 is deformed, and a strain is generated in the strain gauge 31, the first resistance R1 changes, and the potential V3 of the first intermediate point P2 changes. As a result, a potential difference is generated between the first intermediate point P2 and the second intermediate point P4. Therefore, the amount of change in resistance of the strain gauge 31 can be detected by detecting the potential V3 and the potential V4.

As illustrated in FIG. 1, the array layer 30 includes a coupler 101, gate line drive circuits 102, a first signal line selection circuit 103, a second signal line selection circuit 104, a first potential detection line selection circuit 105, and a second potential detection line selection circuit 106 disposed in the peripheral region 6 to drive the load detection circuit.

The coupler 101 is coupled to a drive integrated circuit (IC) disposed outside the stretchable device 100. The drive IC may be mounted as a chip on film (COF) on a flexible printed circuit board or a rigid board, which is not illustrated, and coupled to the coupler 101. Alternatively, the drive IC may be mounted as a chip on glass (COG) in the peripheral region 6 of the first stretchable resin 60.

The gate line drive circuit 102 is a circuit that drives a plurality of gate lines 41 (refer to FIG. 7) based on various control signals supplied from the drive IC. The gate line drive circuit 102 sequentially or simultaneously selects the gate lines 41 and supplies gate drive signals to the selected gate line 41.

The first signal line selection circuit 103 is a switch circuit that sequentially or simultaneously selects a plurality of first signal lines 42. The first signal line selection circuit 103 couples the first signal line 42 to the drive IC based on selection signals supplied from the drive IC. As a result, the predetermined first potential V1 is applied to the first signal line 42.

The second signal line selection circuit 104 is a switch circuit that sequentially or simultaneously selects a plurality of second signal lines 43. The second signal line selection circuit 104 couples the second signal line 43 to the drive IC based on selection signals supplied from the drive IC. As a result, the predetermined second potential V2 is applied to the second signal line 43. The second potential V2 according to the present embodiment is 0 V.

The first potential detection line selection circuit 105 is a switch circuit that sequentially or simultaneously selects a plurality of first potential detection lines 55. The first potential detection line selection circuit 105 couples the selected first potential detection line 55 to the drive IC based on selection signals supplied from the drive IC. As a result, the potential V3 of the first intermediate point P2 is transmitted to the drive IC.

The second potential detection line selection circuit 106 is a switch circuit that sequentially or simultaneously selects a plurality of second potential detection lines 56. The second potential detection line selection circuit 106 couples the selected second potential detection line 56 to the drive IC based on selection signals supplied from the drive IC. As a result, the potential V4 of the second intermediate point P4 is transmitted to the drive IC.

Next, the insulating layers constituting the array layer 30 are described. The material of the insulating layers is photosensitive organic or inorganic material, for example. More specifically, examples of the photosensitive organic material include, but are not limited to, polyimide, acrylic, polybenzoxazole (PBO), phenol, etc. Examples of the inorganic material film include, but are not limited to, SiO, SiN, etc. The elongation of the insulating layers made of these materials is approximately 10%, which is smaller than that of the resin base member 10.

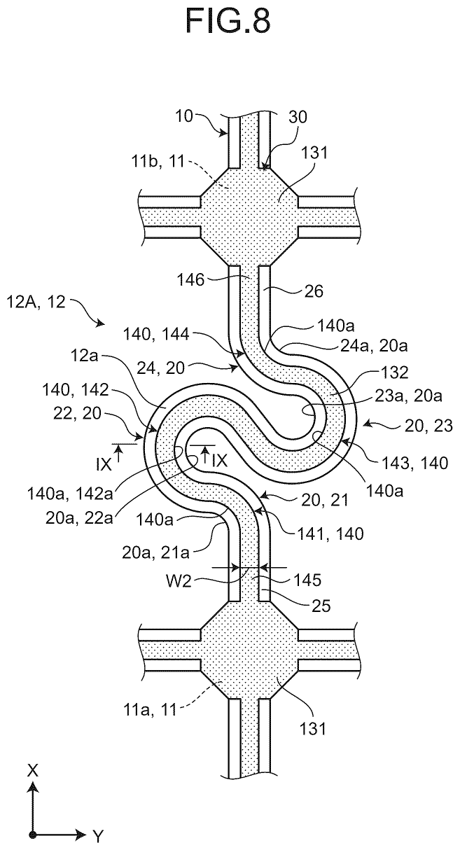

FIG. 8 is an enlarged view of the array layer according to the first embodiment when viewed from the first stacking direction. In FIG. 8, the area of the array layer 30 is illustrated with dots to make it easier to distinguish between the resin base member 10 and the array layer 30. As illustrated in FIG. 8, the array layer 30 includes a plurality of body array layers 131 stacked on the bodies 11 and a plurality of hinge array layers 132 stacked on the hinges 12.

The body array layer 131 is formed in an octagonal shape in plan view and has the same shape as that of the body 11. The hinge array layer 132 extends along the hinge 12 and is coupled to the body array layers 131 at both ends.

The hinge array layer 132 includes arc array layers 140 stacked on the arcs 20. The arc array layers 140 include a first arc array layer 141 stacked on the first arc 21, a second arc array layer 142 stacked on the second arc 22, a third arc array layer 143 stacked on the third arc 23, and a fourth arc array layer 144 stacked on the fourth arc 24. The hinge array layer 132 includes a first base array layer 145 stacked on the first base 25 and a second base array layer 146 stacked on the second base 26.

The width W2 of the hinge array layer 132 is constant from one end of the hinge array layer 132 to the other. In other words, the widths of the first arc array layer 141, the second arc array layer 142, the third arc array layer 143, the fourth arc array layer 144, the first base array layer 145, and the second base array layer 146 are W2.

The width W2 of the hinge array layer 132 is smaller than the width W1 of the hinge 12 (refer to FIG. 4). Therefore, part of a surface 12a of the hinge 12 in the first stacking direction Z1 is not covered by the hinge array layer 132.

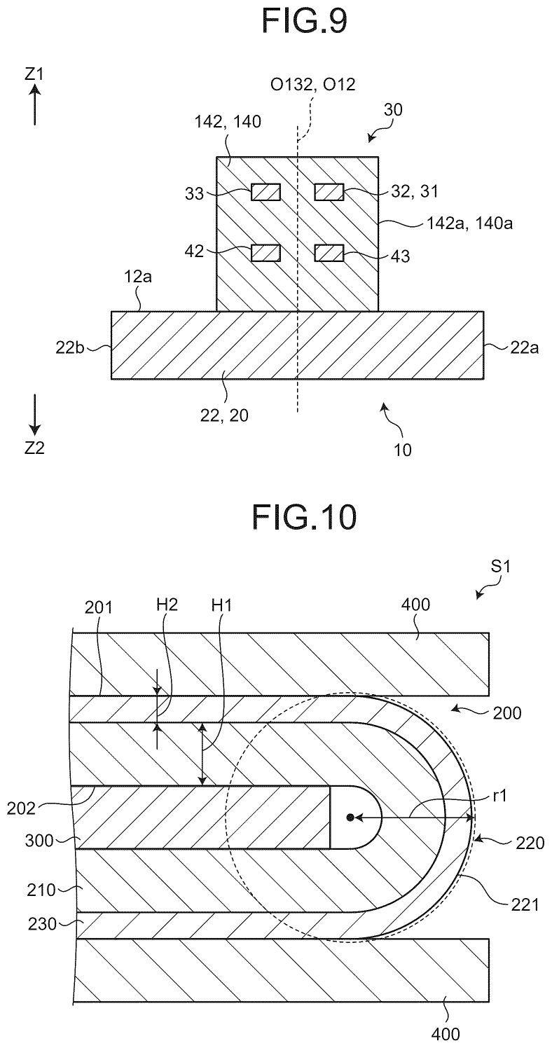

FIG. 9 is a sectional view seen in the direction of arrow along line IX-IX of FIG. 8. As illustrated in FIG. 9, in the stacking direction, the center O132 of the hinge array layer 132 in the width direction coincides with the center O12 of the hinge 12 in the width direction. In other words, the hinge array layer 132 is disposed at the center of the hinge 12 in the width direction. Therefore, an inner periphery 140a of the arc array layer 140 (inner periphery 142a of the second arc array layer 142 in FIG. 9) is disposed away from the inner periphery 22a of the second arc 22 toward the outer periphery 22b of the second arc 22.

Thus, the hinge array layer 132 according to the present embodiment does not overlap the inner peripheral portion of the arc 20 (refer to the areas indicated by arrows N1 to N4 in FIG. 5). In other words, if a tensile load acts on the hinge 12, the arc array layer 140 is not subjected to a large tensile load.

Next, the advantageous effects of the first embodiment are described. Typically, the elongation of the resin base member 10 is approximately 30% or larger, and the elongation of the insulating layers included in the array layer 30 is approximately 10%. This difference in elongation can be ascertained by performing a bending test. When a bending test is performed, cracks are generated in the insulating layers, but not in the resin base member. The following describes a bending test commonly performed. The bending test includes three steps of a first step S1, a second step S2, and a third step S3.

FIG. 10 is a sectional view for explaining the first step of the bending test. At the first step S1 of the bending test, a sample 200 including a resin base member 210 and an insulating layer 230 stacked on the resin base member 210 is prepared. The thickness H1 of the resin base member 210 is 5 μm, and the thickness H2 of the insulating layer 230 is 1.5 μm.

Subsequently, the sample 200 is bent and folded in two. The sample 200 is bent such that parts of the back surface 202 of the sample 200 face each other. A spacer 300 is inserted between the parts of the back surface 202 of the sample 200. The sample 200 is sandwiched by two flat plates 400 so as to come into contact with the spacer 300.

In this way, a folded portion 220 with a cross section in an arc shape is formed in part of the sample 200. At the first step S1, the radius of curvature r1 of a surface 221 of the folded portion 220 is 0.2 mm. At the first step S1, no cracks are generated in the resin base member 210 or the insulating layer 230. In FIG. 10 and other figures, an imaginary circle with the radius of curvature r1 overlaps the surface 221 and is difficult to see. For this reason, the imaginary circle with the radius of curvature r1 is illustrated as a circle having a slightly larger diameter than the surface 221.

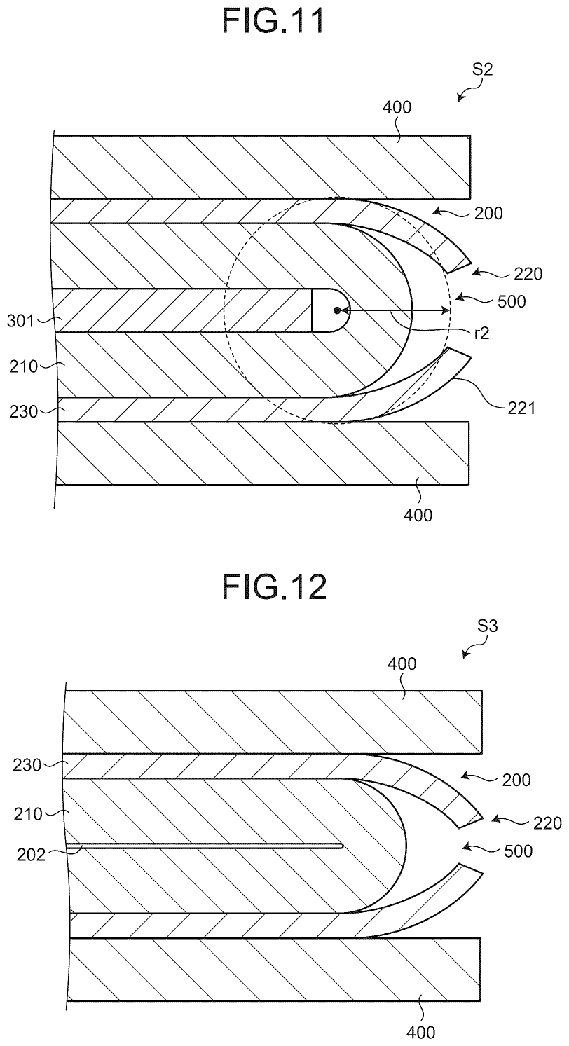

FIG. 11 is a sectional view for explaining the second step of the bending test. At the second step S2 of the bending test, a spacer 301 thinner than the spacer 300 used at the first step S1 is used. The radius of curvature r2 of the surface 221 of the folded portion 220 is smaller than 0.2 mm. As a result, a crack 500 is generated in the part of the insulating layer 230 serving as the folded portion 220.

FIG. 12 is a sectional view for explaining the third step of the bending test. At the third step S3 of the bending test, the spacer 301 used at the second step S2 is removed, and the parts of the back surface 202 of the sample 200 are brought into contact with each other. Also, at the third step S3, no cracks are generated in the resin base member 210.

Thus, when a large tensile load acts on the stretchable device 100, a strain is generated in the resin base member 10, and cracks may possibly be generated in the hinge array layer 132. However, the hinge array layer 132 according to the present embodiment is not disposed at a position on which a large tensile load acts (near an inner periphery 20a of the arc 20) as illustrated in FIGS. 8 and 9. In other words, the arc array layer 140 is disposed so as not to be subjected to a large tensile load. Therefore, cracks are less likely to be generated in the inner periphery portion of the arc array layer 140.

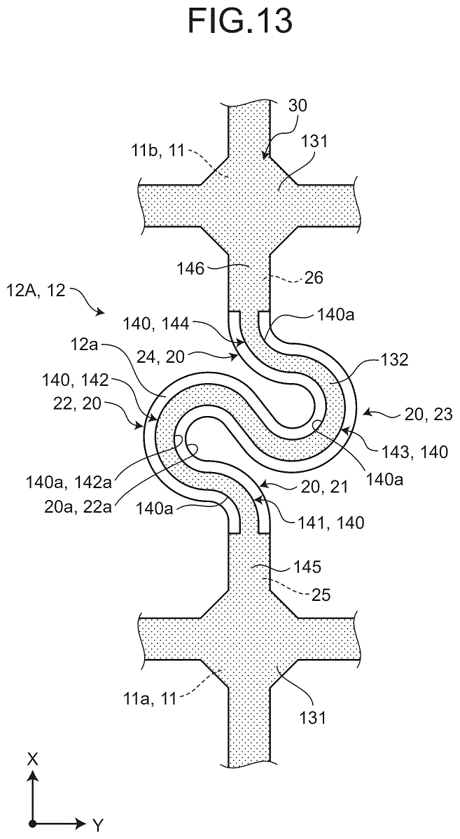

While the first embodiment has been described above, the present disclosure is not limited to the example described in the first embodiment. While the size in the width direction of the hinge array layer 132 according to the first embodiment is constant from one end to the other and is equal to the width W2 of the arc array layer 140, the present disclosure is not limited thereto. FIG. 13 is an enlarged view of the array layer according to a first modification when viewed from the first stacking direction. As illustrated in FIG. 13, for example, the size in the width direction of the first base array layer 145 and the second base array layer 146 may be equal to the width W1 of the hinge 12. Also in this modification, the arc array layer 140 is separated from the inner periphery 20a of the arc 20. Therefore, cracks are less likely to be generated in the arc array layer 140.

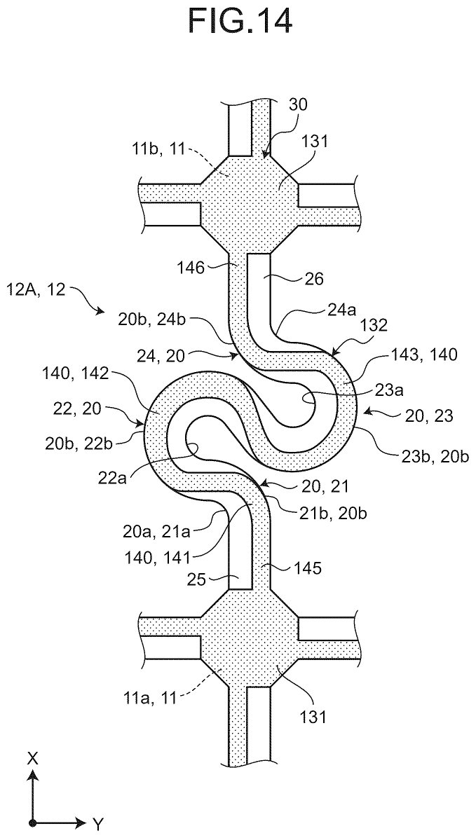

While the hinge array layer 132 (arc array layer 140) according to the first embodiment is disposed at the center of the hinge 12 (arc 20) in the width direction, the arc array layer 140 according to the present disclosure simply needs to be separated from the inner periphery 20a of the arc 20, and the present disclosure is not limited to the example described in the first embodiment. FIG. 14 is an enlarged view of the array layer according to a second modification when viewed from the first stacking direction. As illustrated in FIG. 14, for example, the arc array layer 140 may be disposed closer to an outer periphery 20b of the arc 20 than to the inner periphery 20a. With this configuration, when a tensile load acts on the hinge 12, a compressive load acts on the arc array layer 140. The insulating layers included in the array layer 30 have low elongation but have high durability against compressive loads. Therefore, cracks are less likely to be generated in the arc array layer 140.

What is claimed is:

1. A stretchable device comprising
a stretchable substrate comprising a resin base member and an array layer stacked in sequence, wherein
the resin base member comprises:
a plurality of bodies spaced apart from each other in a planar direction intersecting a stacking direction in which the resin base member and the array layer are stacked; and
a plurality of hinges that meander and extend in the planar direction and couple the bodies,
each of the hinges has an arc having an arc shape when viewed in the stacking direction,
a part of the array layer stacked on the hinge is a hinge array layer,
a part of the hinge array layer stacked on the arc is an arc array layer having an arc shape,
the width of the arc array layer from an inner periphery to an outer periphery is smaller than the width of the arc from an inner periphery to an outer periphery, and
the inner periphery of the arc array layer is disposed away from the inner periphery of the arc toward the outer periphery of the arc.

2. The stretchable device according to claim 1, wherein the arc array layer is disposed at a center of the arc in a width direction.

3. The stretchable device according to claim 1, wherein the arc array layer is disposed closer to the outer periphery of the arc than to the inner periphery.

4. The stretchable device according to claim 1, wherein the size in a width direction of the hinge array layer from one end to the other end is constant and is equal to the width of the arc array layer.

5. The stretchable device according to claim 2, wherein the size in a width direction of the hinge array layer from one end to the other end is constant and is equal to the width of the arc array layer.

6. The stretchable device according to claim 3, wherein the size in a width direction of the hinge array layer from one end to the other end is constant and is equal to the width of the arc array layer.
